(19) United States
(12) Patent Application Publication
(10) Pub. No.: US 2006/0151814 A1
(43) Pub. Date: Jul. 13, 2006

(54) Optical semiconductor device

(75) Inventors: Ryoichi Ito, Kyoto-shi (JP); Hisatada Yasukawa, Kyotanabe-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., Osaka (JP)

(21) Appl. No.: 10/523,799

(22) PCT Filed: Nov. 10, 2003
(86) PCT No.: PCT/JP03/14278

§ 371 Date: Feb. 9, 2005

(30) Foreign Application Priority Data
Nov. 28, 2002 (JP) 2002345178

(51) Int. Cl. H01L 31/112

(52) U.S. Cl. 257/257

(57) ABSTRACT

Since a plurality of light-receiving elements have heretofore led an electrode from a semiconductor substrate through an impurity-diffused and -buried region, series resistance has been relatively high, so that it has been difficult to improve the frequency characteristics of the light-receiving element. The present invention reduces parasitic capacitance by isolating the light-receiving elements from one another with insulator or dielectric isolation regions 6 and further reduces series resistance by making a direct contact with a P-type semiconductor substrate 2 functioning as an anode region through the medium of a conductor-buried region 11 formed by burying a low-resistance conductor in an opening formed in the isolation region 6, so that the frequency characteristics of the light-receiving element can be improved.

### TECHNICAL FIELD

The present invention relates to a light-receiving element and a circuit-including light-receiving element which process photoelectric conversion signals, and more particularly to an optical semiconductor device implementing a light-receiving element and a circuit-including light-receiving element which operate at high speed through their series resistance reduction.

### BACKGROUND ART

As to optical disk apparatus for CDs, DVDs and so on, an optical semiconductor device which has a plurality of light-receiving regions in order to detect laser beams reflected from the disks has been heretofore used. With the development of smaller-sized and higher-performance optical disk apparatus, a circuit-including light-receiving element which is resistant to external noise and operates at high speed has been becoming mainstream in recent years. In addition, in order to implement higher-performance optical disk apparatus for DVDs, a higher-speed higher-sensitivity lower-noise optical semiconductor device has been further demanded.

In conventional optical semiconductor devices, since an electrode is led from a semiconductor substrate through an impurity-diffused and -buried region, they have had relatively high series resistance, so that there has been a limitation on an improvement in frequency characteristics of their light-receiving element (see, for example, Japanese Patent No. 2793085). However, the frequency characteristics of the light-receiving element can be improved by reducing its parasitic capacitance through trench isolation. In addition to this, the improvement in the frequency characteristics of the light-receiving element through the reduction in series resistance has not yet been proposed as well (see, for example, Japanese Patent Laid-Open No. 213917/1997).

In the following, the structure of a conventional optical semiconductor device and its problem will be described with reference to drawings.

FIG. 6 is a sectional view showing the structure of a conventional optical semiconductor device. In FIG. 6, reference numeral 101 is a light-receiving element-forming region. Reference numeral 102 is a P-type semiconductor substrate, reference numeral 103 is an N-type semiconductor layer-forming layer (region) formed on the P-type semiconductor substrate 102, reference numeral 104 is an insulating film formed on the N-type semiconductor layer (103), reference numeral 105 is an antireflection film formed on the light-receiving element, and reference numeral 106 is an insulator or dielectric isolation region which isolates a plurality of light-receiving elements from one another. Reference numeral 107 is a cathode region of the light-receiving region, reference numeral 108 is a cathode contact region formed on the cathode region 107, and reference numeral 109 is a cathode electrode formed on the cathode contact region 108. Further, reference numeral 110 is an anode-leading region selectively formed on the P-type semiconductor substrate 102 which functions as an anode region, reference numeral 111 is an anode contact region formed on the anode-leading region 110, and reference numeral 112 is an anode electrode formed on the anode contact region 111.

In such a light-receiving element in which the P-type semiconductor substrate 102 functions as the anode region and the N⁻-type region on the P-type semiconductor substrate 102 functions as the cathode region 107, light enters into the light-receiving region, so that electron-hole pairs are formed. The carriers thus formed are drifted by an electric field in a depletion layer proximate to the PN junction portion of the light-receiving element to which a reverse bias has been applied. The carriers are then output from the electrode as a photoelectric current. Although a diffusion current resulting from a carrier concentration gradient is also output from the electrode as a photo-electric current, its diffusion time is generally longer than its drift running time, which has become one of the factors that degrade the frequency characteristics of the light-receiving element.

In addition, since the anode portion leads its electrode from the semiconductor substrate through the impurity-diffused and -buried region, it has a relatively high series resistance, which has made it difficult to improve the frequency characteristics of the light-receiving element.

An object of the present invention is to provide an optical semiconductor device which is capable of improving the frequency characteristics of its light-receiving element through reduction in series resistance, and which is further capable of preventing degradation in the frequency characteristics of the light-receiving element resulting from low-speed diffusion transfer carrier components.

### DISCLOSURE OF THE INVENTION

The optical semiconductor device of the invention comprises a plurality of light-receiving elements comprised of a semiconductor region of a first conductivity type and a semiconductor region of a second conductivity type formed on the semiconductor region of the first conductivity type, an isolation region formed by burying an insulator or a dielectric in a trench which passes trough the semiconductor region of the second conductivity type and reaches the semiconductor region of the first conductivity type in order to isolate the respective light-receiving elements from one another, an electrode formed on the isolation region, and a contact portion formed by burying a conductor in an opening which passes through the isolation region and reaches the semiconductor region of the first conductivity type in order to electrically connect the electrode and the semiconductor region of the first conductivity type.

According to the construction, parasitic capacitance can be reduced by isolating the respective light-receiving elements from one another with the insulator or dielectric isolation region, so that the frequency characteristics of the light-receiving element can be improved. Further, since the contact portion formed by burying the conductor in the opening formed in the isolation region electrically connects the electrode and the semiconductor region of the first conductivity type constituting the light-receiving element, series resistance can be reduced, so that the frequency characteristics of the light-receiving element can be improved further.

That is, according to the formula f=1/(2πRC) (where R is a series resistance, and C is a parasitic capacitance) which determines the frequency characteristics of the light-receiving element, the frequency characteristics can be synergistically improved by reducing not only the parasitic capacitance but the series resistance.

Also, according to the invention, carriers generated at all the light-receiving elements can be uniformly drawn up through the shortest route by adopting a construction in which the contact portion formed by burying the conductor in the opening is located so as to surround all the light-receiving elements, so that the frequency characteristics can be improved even further.

Further, according to the invention, it is preferable that the semiconductor region of the first conductivity type comprise an upper layer, a meddle layer, and a lower layer, the middle layer contain a higher concentration of impurity of the first conductivity type than the upper and lower layers do, and the opening in which the conductor is buried be formed so as to reach the middle layer of the semiconductor region of the first conductivity type. According to the construction, by making the concentration of the impurity contained in the middle layer of the semiconductor region of the first conductivity type higher, low-speed diffusion transfer carrier components generated at the lower layer under the middle layer can be cut off, so that the degradation of the frequency characteristics can be prevented. Further, since the conductor buried in the opening connects the electrode and the middle layer having the higher impurity concentration, the series resistance can be reduced by the middle layer having the higher impurity concentration. As a result, the series resistance can be reduced greatly, so that the frequency characteristics of the light-receiving element can be improved even further.

Still further, according to the invention, the connection resistance value of the conductor and the semiconductor region of the first conductivity type can be lowered by providing a high-concentration region, which contains a higher concentration of impurity of the first conductivity type than the semiconductor region of the first conductivity type, directly under the conductor.

Still further, according to the invention, it is preferable that a low-resistance material, such as doped polysilicon or tungsten, be used as the conductor.

According to the invention, it is preferable to adopt a construction that a circuit connected to the light-receiving element is included on a semiconductor region of the first conductivity type other than the light-receiving element-forming region. As described above, by including the circuit in a single chip, an optical semiconductor device which is particularly resistant to external noise and is capable of operating at high speed can be implemented.

### BRIEF DESCRIPTION OF THE DRAWINGS

FIG. 1 is a sectional view showing the structure of an optical semiconductor device according to a first embodiment of the invention.

FIG. 2 is a sectional view showing the structure of an optical semiconductor device according to a second embodiment of the invention.

FIG. 3 is a sectional view showing the structure of an optical semiconductor device according to a third embodiment of the invention.

FIG. 4 is a sectional view showing the structure of an optical semiconductor device according to a fourth embodiment of the invention.

FIG. 5 is a circuit diagram of a current-voltage conversion circuit according to the fourth embodiment of the invention.

FIG. 6 is a sectional view showing the structure of a conventional optical semiconductor device.

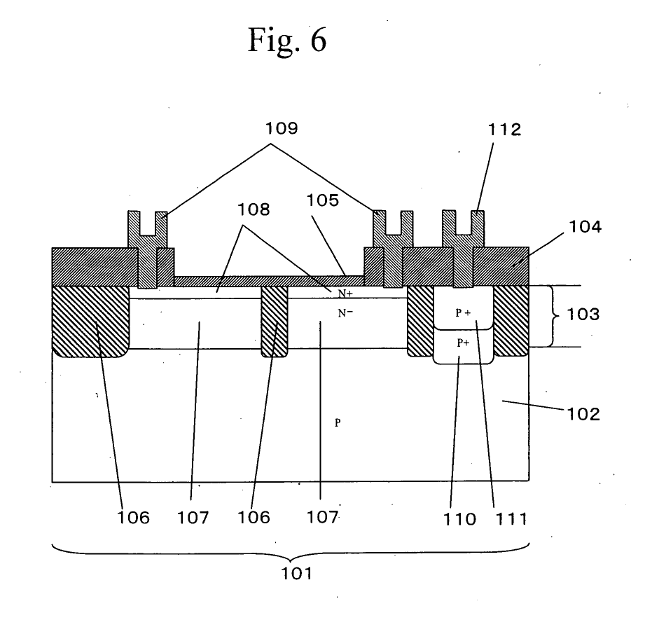

### BEST MODE FOR CARRYING OUT THE INVENTION

In the following, embodiments of the invention will be described with reference to the drawings.

### First Embodiment

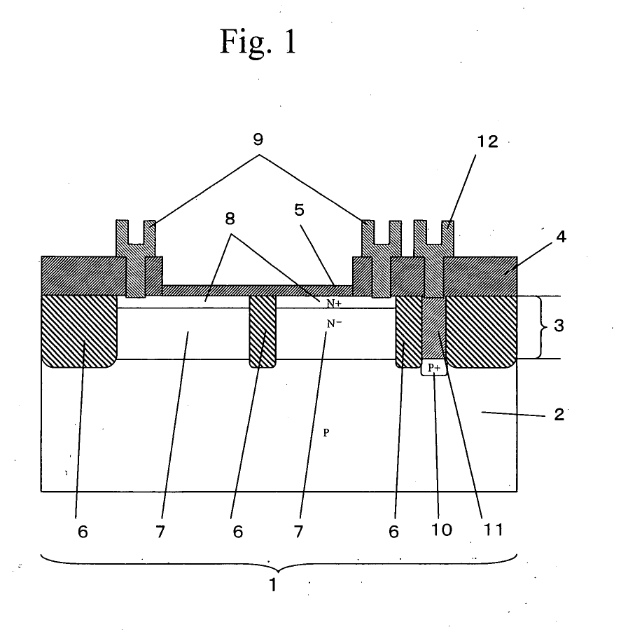

FIG. 1 is a sectional view showing the structure of an optical semiconductor device according to the first embodiment of the invention. In FIG. 1, reference numeral 1 is a light-receiving element-forming region in which a plurality of light-receiving elements (photodiodes) are formed. Reference numeral 2 is a P-type semiconductor substrate, reference numeral 3 is an N-type semiconductor layer-forming layer (region) formed on the P-type semiconductor substrate 2, reference numeral 4 is an insulating film formed on the N-type semiconductor layer (3), reference numeral 5 is an antireflection film formed on the light-receiving element, and reference numeral 6 is an insulator or dielectric isolation region which isolates the plurality of light-receiving elements from one another. Reference numeral 7 is a cathode region of the light-receiving element, reference numeral 8 is a cathode contact region formed on the cathode region 7, and reference numeral 9 is a cathode electrode formed on the cathode contact region 8. Further, reference numeral 10 is an anode-leading region comprising a P⁺-type region selectively formed on the P-type semiconductor substrate 2 which functions as an anode region, and reference numeral 11 is a low-resistance conductor-buried region for making an anode contact with a region opened in the isolation region 6 by etching. Reference numeral 12 is an anode electrode formed on the conductor-buried region 11. The N-type semiconductor layer (3) formed on the P-type semiconductor substrate 2 is present as an N⁻-type region which constitutes the cathode region 7 and an N⁺-type region which constitutes the cathode contact region 8.

Described is one example of the methods of fabricating the optical semiconductor device according to the first embodiment. First, the N-type semiconductor layer-forming layer 3 is formed on the P-type semiconductor substrate 2 by epitaxial growth. Next, for instance, the N-type semiconductor layer-forming layer 3 is selectively etched, and the layer 3 is locally subjected to thermal oxidation, such as pyrogenic oxidation or the like, to grow an oxide film through recess LOCOS, by which the isolation region 6 comprising the oxide film is formed. Thereafter, extremely shallow low-acceleration ion implantation of an N-type impurity is performed in the surface of the N-type semiconductor layer-formed layer 3 to form the cathode contact region 8, by which the cathode region 7 is determined concurrently. Then, for instance, the predetermined portion of the isolation region 6 is dry etched to form an opening which reaches the P-type semiconductor substrate 2, after which ion implantation of a P⁺-type impurity is performed in the opening to form the anode-leading region 10. Further, P-type impurity-doped polysilicon of a P-type impurity is buried in the opening, after which only the doped polysilicon of the surface is removed by etch back to form the conductor-buried region 11. Next, for instance, after a Si—N film is formed by low pressure CVD, an oxide film is formed by atmospheric pressure CVD, thereby the insulating film 4 (comprising the Si—N film and the oxide film) is formed on the entire surface. Next, in order to make contact with the cathode contact region 8 and the conductor-buried region 11, the predetermined portion of the insulating film 4 is selectively dry etched to form an opening. Then, aluminum is deposited in the opening by sputtering, followed by the formation of the cathode electrode 9 and the anode electrode 12 through patterning. Finally, the oxide film formed by the above atmospheric pressure CVD is removed only in the antireflection film region of the light-receiving portion by wet etching to form the antireflection film 5 (comprising the above Si—N film), thereby the optical semiconductor device according to the first embodiment is completed.

Since carriers are generated by light absorbed near the PN junction portion of the P-type semiconductor substrate 2 functioning as the anode region and the cathode region 7 to be output outside as a photoelectric current, the structure according to the first embodiment is advantageous in terms of its light-receiving sensitivity to infrared light which has a great penetration depth particularly when silicon is used as its semiconductor material. In particular, since the light-receiving elements are isolated from one another by the insulator or dielectric isolation region 6, their parasitic capacitance is reduced. In addition, since a direct contact is made from the P-type semiconductor substrate 2 functioning as the anode region by burying the low-resistance conductor (11), their series resistance is reduced, which improves the frequency characteristics of the light-receiving element represented by the formula f=1/(2πRC) (where R is a series resistance, and C is a parasitic capacitance).

### Second Embodiment

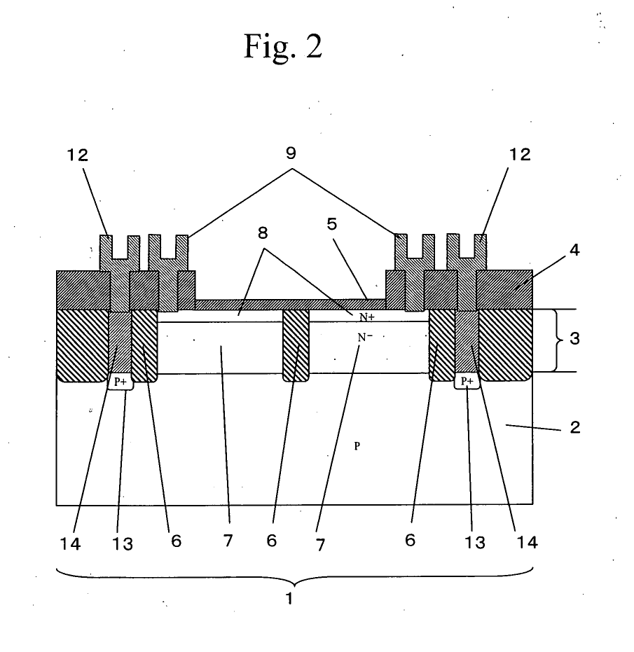

FIG. 2 is a sectional view showing the structure of an optical semiconductor device according to the second embodiment of the invention. In FIG. 2, reference numeral 13 is an anode-leading region comprising a P⁺-type region under a trench selectively formed on a P-type semiconductor substrate 2, and reference numeral 14 is a region in which a low-resistance conductor is buried in order for the perimeter of a light-receiving region to make an anode contact with a region in which an opening having a trench structure is made. The other construction is the same as that of the first embodiment.

According to the second embodiment, the contact is made under the trench by surrounding the perimeter of the light-receiving region in which a plurality of light-receiving elements are formed with the trench structure and burying the conductor in the trench. That is, the conductor-buried region 14 is formed by providing the opening having the trench structure in the insulator or dielectric isolation region 6 so as to surround the perimeter of the light-receiving region in which the plurality of light-receiving elements are formed and by burying the conductor in the opening. In addition, like the conductor-buried region 14, the P⁺-type anode-leading region 13 directly under the conductor-buried region 14 and the anode electrode 12 on the conductor-buried region 14 are formed so as to surround the perimeter of the light-receiving region.

The method of fabricating the optical semiconductor device having the structure disclosed in the second embodiment differs from the method of fabricating the optical semiconductor device having the structure disclosed in the first embodiment only in its P⁺-type anode-leading region 13, conductor-buried region 14, and region (area) in which the anode electrode 12 is formed, and the others can be fabricated as in the case of the first embodiment.

According to the second embodiment, the same effects as those of the first embodiment can be obtained. In addition, since carriers generated at the P-type semiconductor substrate 2 functioning as the anode region can be uniformly drawn up through the shortest route by adopting the above structure, its frequency characteristics can be improved even further.

### Third Embodiment

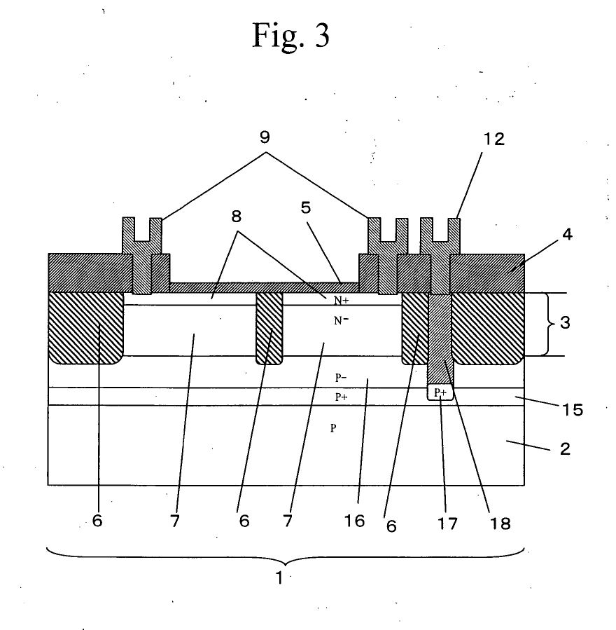

FIG. 3 is a sectional view showing the structure of an optical semiconductor device according to the third embodiment of the invention. In FIG. 3, reference numeral 15 is a P⁺-type buried region formed on a P-type semiconductor substrate 2, and reference numeral 16 is a P⁻-type anode region formed on the P⁺-type buried region 15. Reference numeral 17 is an anode-leading region which is in contact with the P⁺-type buried layer 15 and comprises a P⁺-type region which has a P-type impurity concentration equal to or higher than that of the P⁺-type buried region 15. Reference numeral 18 is a region in which a low-resistance conductor is buried in order to make an anode contact with a region opened in an isolation region 6 by etching, and the anode-leading region 17 is formed under the region 18. The other components are the same as those of the first embodiment.

Unlike the first embodiment, the third embodiment has a construction in which the anode contact is made with the P⁺-type buried region 15 by forming the P⁺-type buried region 15 directly under the light-receiving region. By making the impurity concentration of the P⁺-type buried region 15 higher than that of the P-type semiconductor substrate 2, its potential barrier becomes high. As a result, low-speed diffusion-transfer carrier components generated directly under the P⁺-type buried region 15 can be cut off, which makes it possible to prevent the degradation of its frequency characteristics. Further, the presence of the P⁺-type buried region 15 reduces series resistance. Still further, by adopting the structure in which the contact is directly made with the P⁺-type buried region 15 by burying the low-resistance conductor, the series resistance can be reduced substantially, which makes it possible to improve the frequency characteristics of the light-receiving element.

It is unnecessary for the P⁻-type anode region 16 to have a P-type impurity concentration lower than that of the P-type semiconductor substrate 2, but it is important to set its impurity concentration to the extent that its depletion layer extends to the boundary of the P⁻-type anode region 16 and the P⁺-type buried region 15. As a result, carriers generated at the P⁻-type anode region 16 are drifted by its electric field, which allows their fast transfer.

Described is one example of the methods of fabricating the optical semiconductor device disclosed in the third embodiment. First, ion implantation of a P-type impurity is performed on the semiconductor substrate 2 to form the P⁺-type buried region 15, after which the P⁻-type semiconductor layer which functions as the anode region 16 is formed by epitaxial growth.

Further, the N-type semiconductor layer-forming layer 3 is formed on the P⁻-type semiconductor layer by epitaxial growth. Next, for instance, the N-type semiconductor layer-formed layer 3 is selectively etched and locally subjected to thermal oxidation, such as pyrogenic oxidation or the like, to grow an oxide film through recess LOCOS, by which the isolation region 6 comprising the oxide film is formed. Thereafter, extremely shallow low-acceleration ion implantation of an N-type impurity is performed in the surface of the N-type semiconductor layer-forming layer 3 to form the cathode contact region 8, by which the cathode region 7 is determined concurrently. Then, for instance, the predetermined region of the isolation region 6 is dry etched to form an opening which reaches the P⁺-type buried region 15, after which ion implantation of a P⁺-type impurity is performed in the opening to form the anode-leading region 17. Further, P-type impurity-doped polysilicon is buried in the opening, and only the doped polysilicon of the surface is removed by etch back to form the conductor-buried region 18. Next, for instance, the Si—N film is formed by low pressure CVD, after which the oxide film is formed by atmospheric pressure CVD to form the insulating film 4 (comprising the Si—N film and the oxide film) on the entire surface. Further, in order to make the contact with the cathode contact region 8 and the conductor-buried region 18, the predetermined portion of the insulating film 4 is selectively dry etched to make an opening. Still further, aluminum is deposited in the opening by sputtering, followed by the formation of the cathode electrode 9 and the anode electrode 12 through patterning. Finally, the above oxide film formed by atmospheric pressure CVD is removed only in the antireflection film region of the light-receiving portion by wet etching to form the antireflection film 5 (comprising the above Si—N film), thereby the optical semiconductor device according to the third embodiment is completed.

In the above structures described in the first, second, and third embodiments, it becomes possible to reduce the width of insulator or dielectric isolation regions 6 to 1 to 2 μm or less. As a result, the detection accuracy of incident light is improved, the scale of its integration is increased, and the limitation of isolation widths between the light-receiving elements is reduced, so that there is provided an advantage that desired light-receiving portions can be designed.

Also, according to the structures described in the first and third embodiments, it is possible to reduce the opening area of the conductor-buried regions 11 and 18 to several μm□, so that there is provided an advantage that the layout of the elements has a high degree of flexibility.

As to the method of forming the low-resistance conductor-buried region 11, 14, and 18 described in the first, second, and third embodiments, in addition to the method of forming them by, as described previously, burying the doped polysilicon and then removing the doped polysilicon of the surface layer portion through etch back, there is a method of forming them by burying tungsten through plugging.

Also, in the first, second, and third embodiments, the invention has been described by assuming that the first conductivity type is of the P type and the second conductivity type is of the N type; however, even when the conductivity type of each portion is reversed, that is, even when the first conductivity type is of the N type and the second conductivity type is of the P type, the effect in each embodiment remains the same.

### Fourth Embodiment

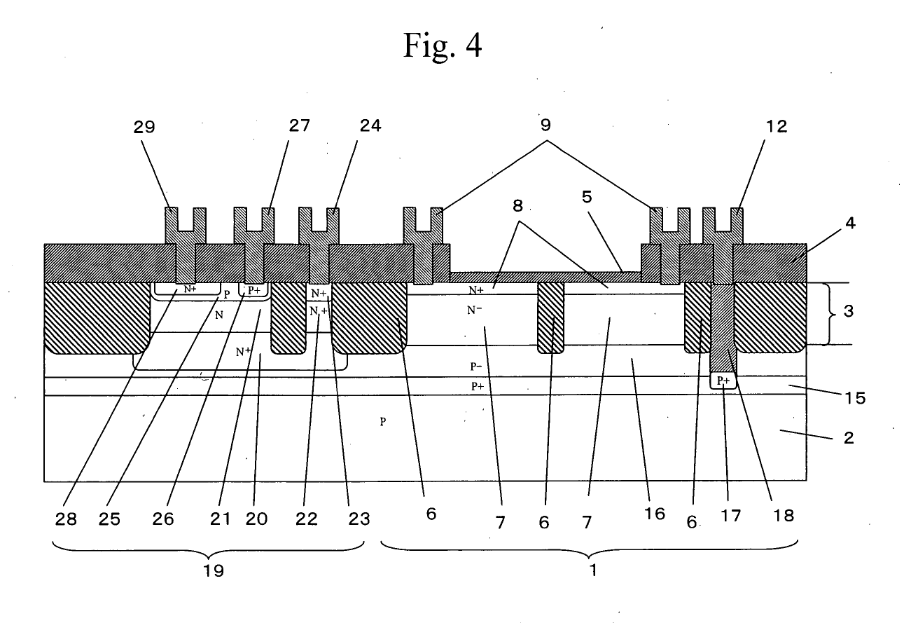

FIG. 4 is a sectional view showing the structure of an optical semiconductor device according to the fourth embodiment of the invention. In FIG. 4, reference numeral 19 is a transistor-forming region. Reference numeral 20 is an N⁺-type collector-buried region, reference numeral 21 is an N-type collector region selectively formed on the N⁺-type collector-buried region 20, reference numeral 22 is an N⁺-type collector-leading region selectively formed on the perimeter of the N⁺-type collector-buried region 20, reference numeral 23 is an N⁺-type collector contact region formed on the N⁺-type collector-leading region 22, and reference numeral 24 is a collector electrode formed on the N⁺-type collector contact region 23. Further, reference numeral 25 is a P-type base region selectively formed on the N-type collector region 21, reference numeral 26 is a P⁺-type base contact region selectively formed on one side of the perimeter of the P-type base region 25, and reference numeral 27 is a base electrode formed on the P⁺-type base contact region 26. Still further, reference numeral 28 is an N⁺-type emitter region selectively formed opposite to the P⁺-type base contact region 26, and reference numeral 29 is an emitter electrode formed on the N⁺-type emitter region 28. The other construction of the light-receiving element-forming region 1 is the same as that described in the third embodiment. The construction of the light-receiving element-forming region 1 may be the same as those described in the first and second embodiments.

An exemplary circuit construction according to the fourth embodiment will be described below.

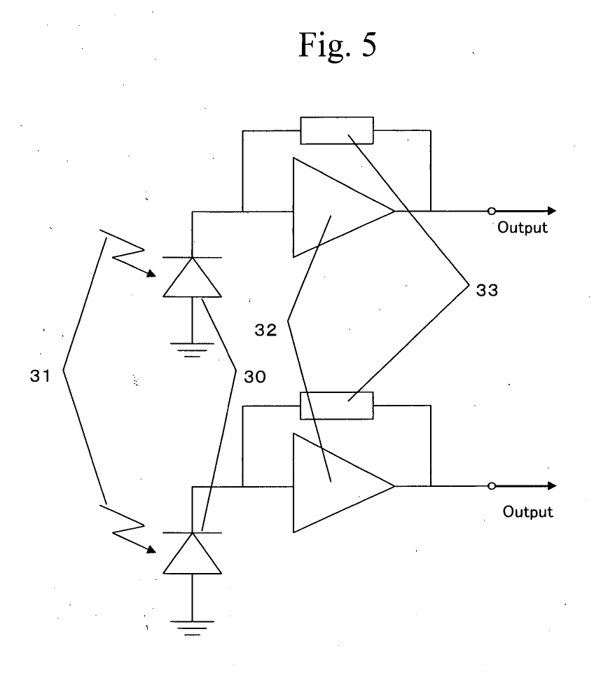

FIG. 5 illustrates a circuit for current-voltage conversion, in which reference numeral 30 is a light-receiving element, reference numeral 31 is an optical signal incident upon the light-receiving element, reference numeral 32 is an amplifier, and reference numeral 33 is an impedance.

In the circuit shown in FIG. 5, the optical signal 31 incident upon the light-receiving element 30 is photoelectrically converted to an electric current. The resulting current is subjected to current-voltage conversion through the amplifier 32 comprised of a transistor, a capacitance element, a resistance element and so on and an impedance 33 to be output as a signal. Optical pickup apparatus for CDs and so on not only detect a signal through optical currents output from each light-receiving region but also generally control their optical pickup device by obtaining a tracking signal and a focus signal through variations in the position and shape of a laser beam using a plurality of light-receiving elements. As described above, by including circuits connected to light-receiving elements on a single chip, an optical semiconductor device particularly resistant to external noise and capable of operating at high speed can be implemented.

1. An optical semiconductor device comprising:
a plurality of light-receiving elements comprised of a semiconductor region of a first conductivity type and a semiconductor region of a second conductivity type formed on the semiconductor region of the first conductivity type;
an isolation region formed by burying an insulator or a dielectric in a trench which passes through the semiconductor region of the second conductivity type and which reaches the semiconductor region of the first conductivity type in order to isolate the respective light-receiving elements from one another;
an electrode formed on the isolation region; and
a contact portion formed by burying a conductor in an opening which passes through the isolation region and which reaches the semiconductor region of the first conductivity type in order to electrically connect the electrode and the semiconductor region of the first conductivity type.

2. The optical semiconductor device of claim 1, wherein the contact portion formed by burying the conductor in the opening is located so as to surround each light-receiving element.

3. The optical semiconductor device of claim 1, wherein the semiconductor region of the first conductivity type comprises an upper layer, a middle layer, and a lower layer, the middle layer contains a higher concentration of impurity of the first conductivity type than the upper and lower layers do, and the opening in which the conductor is buried is formed so as to reach the middle layer of the semiconductor region of the first conductivity type.

4. The optical semiconductor device of claim 1, wherein a high-concentration region, which contains a higher concentration of impurity of the first conductivity type than the semiconductor region of the first conductivity type does, is provided directly under the conductor.

5. The optical semiconductor device of claim 2, wherein a high-concentration region, which contains a higher concentration of impurity of the first conductivity type than the semiconductor region of the first conductivity type does, is provided directly under the conductor.

6. The optical semiconductor device of claim 3, wherein a high-concentration region, which contains a higher concentration of impurity of the first conductivity type than the semiconductor region of the first conductivity type does, is provided directly under the conductor.

7. The optical semiconductor device of claim 1, wherein the conductor is doped polysilicon or tungsten.

8. The optical semiconductor device of claim 2, wherein the conductor is doped polysilicon or tungsten.

9. The optical semiconductor device of claim 3, wherein the conductor is doped polysilicon or tungsten.

10. The optical semiconductor device of claim 4, wherein the conductor is doped polysilicon or tungsten.

11. The optical semiconductor device of claim 5, wherein the conductor is doped polysilicon or tungsten.

12. The optical semiconductor device of claim 6, wherein the conductor is doped polysilicon or tungsten.

13. The optical semiconductor device of claim 1, wherein a circuit connected to the light-receiving element is included on the semiconductor region of the first conductivity type other than the light-receiving element-formed region.

14. The optical semiconductor device of claim 2, wherein a circuit connected to the light-receiving element is included on the semiconductor region of the first conductivity type other than the light-receiving element-formed region.

15. The optical semiconductor device of claim 3, wherein a circuit connected to the light-receiving element is included on the semiconductor region of the first conductivity type other than the light-receiving element-formed region.
